(19) United States
(12) Patent Application Publication
(10) Pub. No.: US 2019/0182989 A1
(43) Pub. Date: Jun. 13, 2019

(54) ADAPTING FRAME FOR RACK DOOR

(71) Applicant: AURAS Technology Co., Ltd., New Taipei City (TW)

(72) Inventors: CHIEN-AN CHEN, New Taipei City (TW); MU-SHU FAN, New Taipei City (TW); CHIEN-YU CHEN, New Taipei City (TW); WEI-HAO CHEN, New Taipei City (TW)

(21) Appl. No.: 16/217,118

(22) Filed: Dec. 12, 2018

Related U.S. Application Data
(60) Provisional application No. 62/597,954, filed on Dec. 13, 2017.

(30) Foreign Application Priority Data
Dec. 7, 2018 (TW) 107144186

(51) Int. Cl. H05K 7/20; H05K 7/18

(52) U.S. Cl. CPC H05K 7/20781; H05K 7/20272; H05K 7/18

(57) ABSTRACT

A rack door adapting frame includes an edge frame assembly and an intermediate frame assembly. The edge frame assembly defines a two-dimensional size corresponding to a rack cabinet. The intermediate frame assembly is disposed within a range of the two-dimensional size of the edge frame assembly. The intermediate frame assembly is provided for connecting a specified part in a fixing manner or a detachable manner.

### CROSS-REFERENCE TO RELATED APPLICATION

This application claims priority to U.S. Provisional Patent Application No. 62/597,954 filed Dec. 13, 2017, the contents of which are incorporated herein by reference.

### FIELD OF THE INVENTION

The present invention relates to a field of a rack cabinet, and more particularly to an adapting frame for a rear rack door and a rack cabinet.

### BACKGROUND OF THE INVENTION

A rack cabinet is an indispensable device for a computing center or a data center. Consequently, the standard association or the industrial association has established a number of standards about the size, the material and the hole position of the rack cabinet for allowing the general manufacturers to follow. For meeting the needs of users, the accessories that increase the value of the rack cabinet must have the standardized and flexible characteristics. Moreover, when a server or a network device placed in the rack cabinet is operated, a liquid-cooling heat exchange system is an essential component. Therefore, it is important for the manufacturer of the rack cabinet to integrate the components of the rack cabinet and the liquid-cooling heat exchange system while making effective use of the space and increasing the heat dissipating efficiency and the maintenance efficiency.

### SUMMARY OF THE INVENTION

For enhancing the use value of the rack cabinet, the present invention provides a rack door adapting frame with a standardized and flexible mechanism for facilitating installing the parts of the liquid-cooling heat exchange system and assembling the accessories of the rack cabinet.

For facilitating the maintenance worker to maintain or check the device or heat exchange system in the rack cabinet, the present invention provides a rack door adapting frame. The rack door adapting frame is arranged between a rack cabinet and a cooling-kit rear door. Consequently, the heat exchange system can be maintained by the maintenance worker more easily.

In accordance with an aspect of the present invention, there is provided a rack door adapting frame. The rack door adapting frame includes an edge frame assembly and an intermediate frame assembly. The edge frame assembly defines a two-dimensional size corresponding to a rack cabinet. The intermediate frame assembly is disposed within a range of the two-dimensional size of the edge frame assembly. The intermediate frame assembly is provided for connecting a specified part in a fixing manner or a detachable manner.

In an embodiment, the rack door adapting frame further includes a jointing mechanism. The edge frame assembly is connected with a cooling-kit rear door through the jointing mechanism. The edge frame assembly is arranged between the rack cabinet and the cooling-kit rear door.

In an embodiment, the edge frame assembly includes an upper rim, a lower rim and two lateral rims, and the two-dimensional size is defined by the upper rim, the lower rim and the two lateral rims collaboratively.

In an embodiment, the intermediate frame assembly is connected between the two lateral rims. A first space and a second space over the first space are defined by the intermediate frame assembly and the two lateral rims collaboratively.

In an embodiment, the first space is aligned with a coolant distribution unit in the rack cabinet, and/or the second space is aligned with the specified part.

In an embodiment, the specified part includes two working liquid channel assemblies, which are connected with the upper rim and the intermediate frame assembly in the fixing manner or the detachable manner.

In an embodiment, the two working liquid channel assemblies are parallel with or substantially parallel with the two lateral rims.

In an embodiment, each of the working liquid channel assemblies collects a working liquid from a manifold of an electronic device in the rack cabinet, or the working liquid is introduced into the manifold of the electronic device in the rack cabinet.

In an embodiment, the electronic device in the rack cabinet is a server or a network device.

In an embodiment, each of the working liquid channel assemblies includes a working liquid main pipe and a first liquid inlet/outlet. The first liquid inlet/outlet is located at a sidewall of the working liquid main pipe.

In an embodiment, the first liquid inlet/outlet faces the rack cabinet.

In an embodiment, the first liquid inlet/outlet is coupled with the manifold of the electronic device.

In an embodiment, each of the working liquid channel assemblies further includes a second liquid inlet/outlet. The second liquid inlet/outlet is located at the sidewall of the working liquid main pipe and coupled with a coolant distribution unit in the rack cabinet.

In an embodiment, the rack door adapting frame further includes a pump. The pump is installed in the working liquid main pipe.

In accordance with another aspect of the present invention, there is provided a rack door adapting frame. The rack door adapting frame includes an edge frame assembly and an intermediate frame assembly. The edge frame assembly includes two lateral rims. The intermediate frame assembly is used for connecting a specified part in a fixing manner or a detachable manner. The intermediate frame assembly is connected between the two lateral rims. A first space and a second space over the first space are defined by the intermediate frame assembly and the two lateral rims collaboratively.

In an embodiment, the rack door adapting frame further includes a jointing mechanism. The edge frame assembly is connected with a cooling-kit rear door through the jointing mechanism. The edge frame assembly is arranged between the rack cabinet and the cooling-kit rear door.

In an embodiment, the specified part includes two working liquid channel assemblies, which are connected with the intermediate frame assembly in the fixing manner or the detachable manner.

In an embodiment, each of the working liquid channel assemblies collects a working liquid from a manifold of an electronic device in the rack cabinet, or the working liquid is introduced into the manifold of the electronic device in the rack cabinet.

In an embodiment, each of the working liquid channel assemblies includes a working liquid main pipe and a first liquid inlet/outlet. The first liquid inlet/outlet is located at a sidewall of the working liquid main pipe.

In an embodiment, each of the working liquid channel assemblies further includes a second liquid inlet/outlet. The second liquid inlet/outlet is located at the sidewall of the working liquid main pipe and coupled with a coolant distribution unit in the rack cabinet.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating an adapting frame according to an embodiment of the present invention and taken along a first viewpoint;

FIG. 2 is a schematic perspective view illustrating the adapting frame according to the embodiment of the present invention and taken along a second viewpoint; and

FIG. 3 is a schematic perspective view illustrating an adapting frame according to another embodiment of the present invention.

### DETAILED DESCRIPTION OF THE PREFERRED EMBODIMENT

For illustration, the structures, organizations or components of the rack door adapting frame shown in the drawings of the present invention are in scale with the elements of the practical product. According to the requirements of descriptions, the components may be scaled up or scaled down in an unequal proportion. The implementations of the rack door adapting frame are not limited by the drawings.

In this context, a rack cabinet is a single or combined cabinet that can be placed in a machine room to support plural servers or network devices in vertical arrangement. The types of the servers are not limited. For example, the servers are file servers, backup servers, web servers, mail servers, or the like. Generally, the main body of the rack cabinet must comply with the hole size specifications that are established by the standard association or the industrial association. In other words, the frame size, the hole number and the hole size of the main body of the rack cabinet are fixed and unchanged. Moreover, while the servers and the network devices are operated at the high speed or a full speed, a great deal of waste heat is generated. If the waste heat is not dissipated away quickly, the waste heat may adversely affect the operating environment of the servers or the network devices. For removing the waste heat quickly, the rack product comprising a rear door with a cooling kit has been introduced into the market. That is, a rear door with a fan array is installed on a rear side of the rack cabinet. The fan array is used for driving an airflow to remove the waste heat from the rack cabinet quickly. The rack door adapting frame of the present invention is used for connecting the cooling-kit rear door with the main body of the standard rack cabinet. It is noted that the rack door adapting frame is not only applied to the cooling-kit rear door. That is, the rack door adapting frame may be applied to the rear door with other components. Moreover, the components of the rack door adapting frame of the present invention are made of the standard materials, and detailed descriptions thereof are omitted.

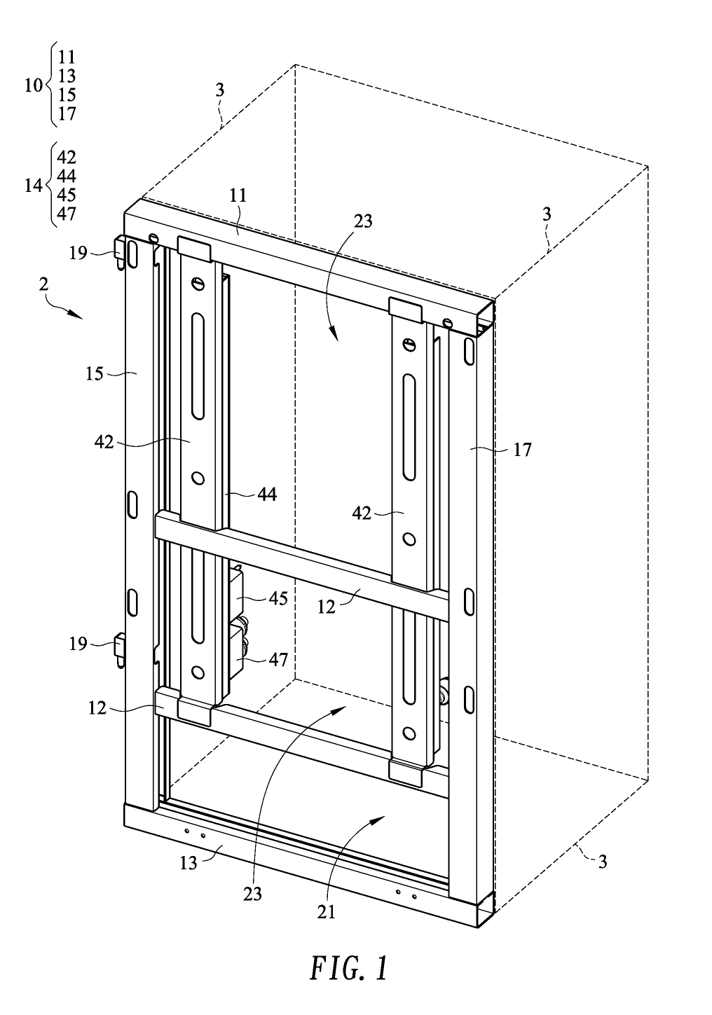

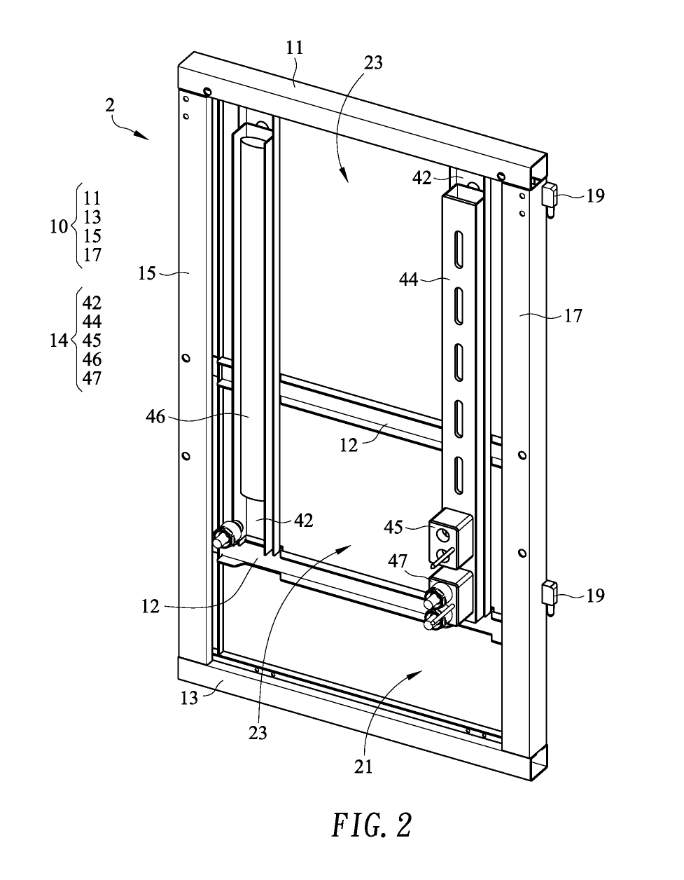

FIG. 1 and FIG. 2 are schematic perspective views illustrating a rack door adapting frame according to an embodiment of the present invention and taken along different viewpoints. The viewpoint of FIG. 1 is taken in the direction from the rear door to the main body of the rack cabinet. The main body of the rack cabinet is indicated by the dotted lines 3. The viewpoint of FIG. 2 is taken in the direction from the main body of the rack cabinet to the rear door. As shown in FIG. 1, the rack door adapting frame 2 comprises an edge frame assembly 10, an intermediate frame assembly 12 and a working liquid channel assembly 14. The edge frame assembly 10 is the main body of the rack door adapting frame 2 to define the length and the width of the rack door adapting frame 2. In addition, the length and the width of the rack door adapting frame 2 are substantially equal to the length and the width of the rack cabinet. In an embodiment, the edge frame assembly 10 comprises an upper rim 11, a lower rim 13, and two lateral rims 15, 17. The upper rim 11 and the lower rim 13 are separated from each other and parallel with each other. In addition, the upper rim 11 and the lower rim 13 have the same length. The two lateral rims 15 and 17 are separated from each other and parallel with each other. In addition, the two lateral rims 15 and 17 have the same length. These rims are fixedly connected with each other through a suitable coupling means. This coupling means is different from the conventional coupling means, and is not redundantly described herein. One of the two lateral rims 15 and 17 is equipped with one or plural jointing mechanisms 19 for connecting the rack cabinet with the cooling-kit rear door. In an embodiment, each jointing mechanism 19 is pivotally coupled to the rack cabinet and/or the cooling-kit rear door. Consequently, the rack door adapting frame 2 is pivotal (i.e., opened or closed) relative to the rack cabinet and/or the cooling-kit rear door. In some other embodiments, the rack door adapting frame 2 is only pivotally coupled to the rack cabinet or the cooling-kit rear door through each jointing mechanism 19. In an embodiment, the edge frame assembly 10 is connected with the cooling-kit rear door (not shown) through each jointing mechanism 19. Consequently, the edge frame assembly 10 is laterally arranged between the main body of the rack cabinet and the cooling-kit rear door. Moreover, the edge frame assembly 10 may be used to fix or connect the intermediate frame assembly 12 and/or the working liquid channel assembly 14.

Please refer to FIG. 1 and FIG. 2. The intermediate frame assembly 12 may be used for connecting a specified part in a fixing manner or a detachable manner. In an embodiment, the intermediate frame assembly 12 comprises one or more linear bars, wherein the linear bar is optionally equipped with a partial bent structure. The intermediate adapting assembly 12 is fixed or connected between the upper rim 11 and the lower rim 13, or the intermediate adapting assembly 12 is fixed or connected between the two lateral rims 15 and 17. Moreover, different spaces are defined by the intermediate adapting assembly 12 within the scope of the edge frame assembly 10 for providing different use purposes. In an embodiment, two spaces 21 and 23 are defined by the intermediate adapting assembly 12. In an embodiment, the space 21 is aligned with a position of the rack cabinet where a coolant distribution unit (CDU) is installed. Consequently, the maintenance worker can directly check coolant distribution unit from the outside. Moreover, the working liquid channel assembly 14 is installed in the space 23. Moreover, the intermediate adapting assembly 12 further comprises guiding rails, coupling holes or any other appropriate connecting mechanisms for connecting other parts in the fixing manner or the detachable manner.

Please refer to FIG. 1 and FIG. 2 again. The working liquid channel assembly 14 comprises two guiding rails 42 that are spaced apart. Moreover, the guiding rail 42 is covered by a covering member 44. The guiding rails 42 are detachably connected with the intermediate adapting assembly 12. Alternatively, the guiding rails 42 are detachably connected with the edge frame assembly 10 and the intermediate adapting assembly 12. Moreover, a working liquid main pipe 46 is installed in the guiding rail 42. That is, the working liquid main pipe 46 is arranged between the guiding rail 42 and the covering member 44. The working liquid main pipe 46 collects the working liquid from the manifolds of plural servers or network devices that are installed in the rack cabinet. Alternatively, through the working liquid main pipe 46, the working liquid with a low temperature is transferred from the outside to the plural servers or network devices that are installed in the rack cabinet. The covering member 44 comprises one or plural liquid inlets 45 and a liquid outlet 47. In an embodiment, the temperatures of the working liquid in the plural working liquid main pipes 46 are different. The working liquid main pipe 46 is made of a soft material or a flexible material. The working liquid main pipe 46 is deformable to withstand the external force. Optionally, the working liquid main pipe 46 is a hard pipe that is made of a rigid material. In this case, the working liquid main pipe 46 is formed of one or plural rotatable/spinnable segments that can withstand the external force in a rotation manner or a spinning manner.

As mentioned above, the rack door adapting frame 2 of the present invention is used for connecting the rack cabinet and the cooling-kit rear door. According to the operating or maintaining requirements, the rack-type liquid-cooling heat exchange system is equipped with a dedicated window for maintaining the coolant distribution unit. The maintenance worker can easily maintain the coolant distribution unit through the window without the need of moving other mechanism or part. Moreover, the working liquid main pipe is installed in the rack door adapting frame 2. Consequently, the external liquid piping system of the liquid-cooling heat exchange system can be easily installed, maintained and configured. Since the configuration of the rack cabinet is more flexible, the traffic line planning efficacy and the area/space utilization of the entire machine room will be enhanced.

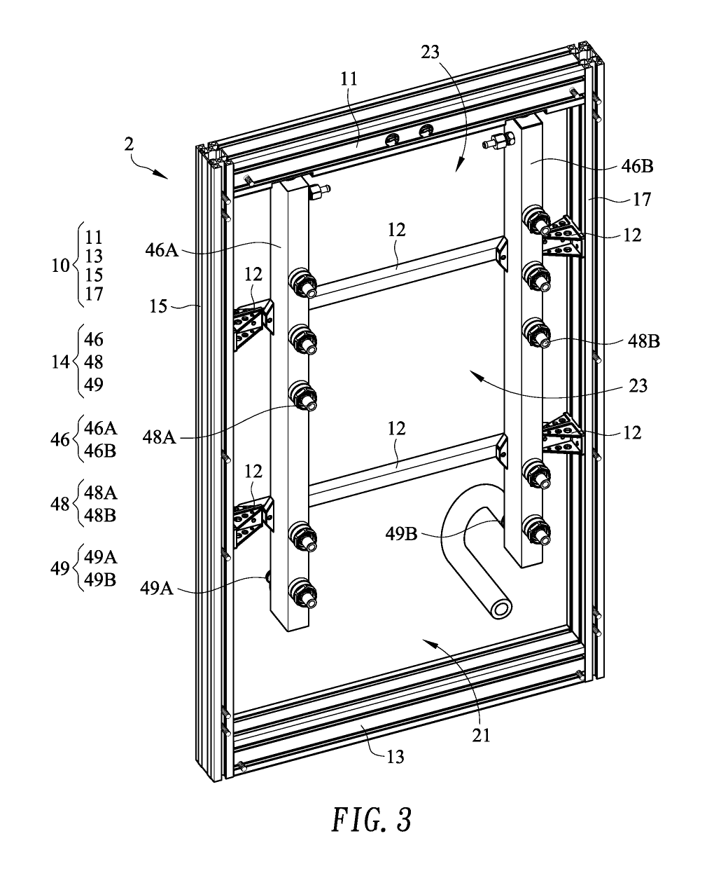

FIG. 3 is a schematic perspective view illustrating an adapting frame according to another embodiment of the present invention. The viewpoint of FIG. 3 is taken in the direction from the main body of the rack cabinet to the rear door. As shown in FIG. 3, the rack door adapting frame 2 comprises an edge frame assembly 10, an intermediate frame assembly 12 and two working liquid channel assemblies 14. A two-dimensional size corresponding to the rack cabinet is defined by the edge frame assembly 10. For example, the two-dimensional size corresponding to the rear surface of the rack cabinet is defined. The edge frame assembly 10 comprises an upper rim 11, a lower rim 13 and two lateral rims 15, 17 for defining a quadrilateral structure with the two-dimensional size. Theses rims are fixedly connected with each other by a suitable connecting means (e.g., a welding means or a screwing means). In some other embodiments, the edge frame assembly 10 at least comprises two lateral rims 15 and 17.

The edge frame assembly 10 is connected between the two lateral rims 15 and 17. A first space 21 and a second space 23 over the first space 21 are defined by the edge frame assembly 10 and the two lateral rims 15 and 17 collaboratively. The edge frame assembly 10 and the two lateral rims 15 and 17 are fixedly connected with each other by a suitable connecting means (e.g., a welding means or a screwing means). The first space 21 is aligned with a coolant distribution unit (not shown) in the rack cabinet. In some embodiments, the first space 21 is laterally arranged beside the coolant distribution unit. The second space 23 is aligned with the working liquid channel assemblies 14 and/or the heat generation element (e.g., a server or a network device) in the rack cabinet. In some embodiments, the second space 23 is laterally arranged beside the server or the network device.

The two working liquid channel assemblies 14 are parallel with or substantially parallel with the two lateral rims. Each working liquid channel assembly 14 collects the working liquid from the manifold (not shown) of the electronic device in the rack cabinet. Alternatively, the working liquid is introduced into the manifold of the electronic device in the rack cabinet through the working liquid channel assembly 14. The electronic device is a server or a network device. The two working liquid channel assemblies 14 comprise plural working liquid main pipes 46 and first-group liquid inlets/outlets 48. The first-group liquid inlets/outlets 48 are located at sidewalls of the working liquid main pipes 46. Moreover, the first-group liquid inlets/outlets 48 face the rack cabinet. The first-group liquid inlets/outlets 48 are coupled to the manifold of the electronic device. In some embodiments, the first-group liquid inlets/outlets 48 are connected to the manifold of the electronic device through a piping system (not shown). After the cooled working liquid is introduced into the manifold of the electronic device (e.g., a server or a network device) through one of the two working liquid main pipes 46 and one of the first-group liquid inlets/outlets 48 (e.g., the first inlet/outlet 48A), the working liquid absorbs the heat from the electronic device. The heated working liquid is introduced into the other working liquid main pipe 46 (e.g., the working liquid main pipe 46B) and another of the first-group liquid inlets/outlets 48 (e.g., the first inlet/outlet 48B). Consequently, the efficacy of dissipating the heat from the electronic device in the liquid-cooling manner is enhanced.

In some embodiments, the two working liquid channel assemblies 14 further comprise second-group liquid inlets/outlets 49. The second-group liquid inlets/outlets 49 are located at sidewalls of the working liquid main pipes 46. Moreover, the second-group liquid inlets/outlets 49 are coupled with the coolant distribution unit of the rack cabinet. After the heated working liquid collected in the working liquid main pipe 46B is transferred to the coolant distribution unit through one of the second-group liquid inlets/outlets 49 (e.g., the second liquid inlet/outlet 49B), the working liquid is cooled down. The cooled working liquid is returned back to the working liquid main pipe 46A through another of the second-group liquid inlets/outlets 49 (e.g., the second liquid inlet/outlet 49A). Consequently, the function of dissipating the heat from the electronic device (e.g., a server or a network device) in the liquid-cooling manner is continuously implemented.

In some embodiments, a pump (not shown) is installed in the working liquid main pipe 46A for moving the cooled working liquid to the first-group liquid inlets/outlets 48 and transferring the cooled working liquid to the manifolds of the corresponding servers or network devices. In some embodiments, the pump is arranged near the upper rim. In some other embodiments, the pump is arranged between the top end of the working liquid main pipe 46 and the first inlet/outlet 48A.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A rack door adapting frame, comprising:
an edge frame assembly for defining a two-dimensional size corresponding to a rack cabinet; and
an intermediate frame assembly disposed within a range of the two-dimensional size of the edge frame assembly, wherein the intermediate frame assembly is provided for connecting a specified part in a fixing manner or a detachable manner.

2. The rack door adapting frame according to claim 1, further comprising a jointing mechanism, wherein the edge frame assembly is connected with a cooling-kit rear door through the jointing mechanism, and the edge frame assembly is arranged between the rack cabinet and the cooling-kit rear door.

3. The rack door adapting frame according to claim 1, wherein the edge frame assembly comprises an upper rim, a lower rim and two lateral rims, and the two-dimensional size is defined by the upper rim, the lower rim and the two lateral rims collaboratively.

4. The rack door adapting frame according to claim 3, wherein the intermediate frame assembly is connected between the two lateral rims, wherein a first space and a second space over the first space are defined by the intermediate frame assembly and the two lateral rims collaboratively.

5. The rack door adapting frame according to claim 4, wherein the first space is aligned with a coolant distribution unit in the rack cabinet, and/or the second space is aligned with the specified part.

6. The rack door adapting frame according to claim 3, wherein the specified part includes two working liquid channel assemblies, which are connected with the upper rim and the intermediate frame assembly in the fixing manner or the detachable manner.

7. The rack door adapting frame according to claim 6, wherein the two working liquid channel assemblies are parallel with or substantially parallel with the two lateral rims.

8. The rack door adapting frame according to claim 6, wherein each of the working liquid channel assemblies collects a working liquid from a manifold of an electronic device in the rack cabinet, or the working liquid is introduced into the manifold of the electronic device in the rack cabinet.

9. The rack door adapting frame according to claim 8, wherein the electronic device in the rack cabinet is a server or a network device.

10. The rack door adapting frame according to claim 6, wherein each of the working liquid channel assemblies comprises a working liquid main pipe and a first liquid inlet/outlet, wherein the first liquid inlet/outlet is located at a sidewall of the working liquid main pipe.

11. The rack door adapting frame according to claim 10, wherein the first liquid inlet/outlet faces the rack cabinet.

12. The rack door adapting frame according to claim 10, wherein the first liquid inlet/outlet is coupled with the manifold of the electronic device.

13. The rack door adapting frame according to claim 10, wherein each of the working liquid channel assemblies further comprises a second liquid inlet/outlet, wherein the second liquid inlet/outlet is located at the sidewall of the working liquid main pipe and coupled with a coolant distribution unit in the rack cabinet.

14. The rack door adapting frame according to claim 10, further comprising a pump, wherein the pump is installed in the working liquid main pipe.

15. A rack door adapting frame, comprising:
an edge frame assembly comprising two lateral rims; and
an intermediate frame assembly for connecting a specified part in a fixing manner or a detachable manner,
wherein the intermediate frame assembly is connected between the two lateral rims, and a first space and a second space over the first space are defined by the intermediate frame assembly and the two lateral rims collaboratively.

16. The rack door adapting frame according to claim 15, further comprising a jointing mechanism, wherein the edge frame assembly is connected with a cooling-kit rear door through the jointing mechanism, and the edge frame assembly is arranged between the rack cabinet and the cooling-kit rear door.

17. The rack door adapting frame according to claim 15, wherein the specified part includes two working liquid channel assemblies, which are connected with the intermediate frame assembly in the fixing manner or the detachable manner.

18. The rack door adapting frame according to claim 17, wherein each of the working liquid channel assemblies collects a working liquid from a manifold of an electronic device in the rack cabinet, or the working liquid is introduced into the manifold of the electronic device in the rack cabinet.

19. The rack door adapting frame according to claim 17, wherein each of the working liquid channel assemblies comprises a working liquid main pipe and a first liquid inlet/outlet, wherein the first liquid inlet/outlet is located at a sidewall of the working liquid main pipe.

20. The rack door adapting frame according to claim 19, wherein each of the working liquid channel assemblies further comprises a second liquid inlet/outlet, wherein the second liquid inlet/outlet is located at the sidewall of the working liquid main pipe and coupled with a coolant distribution unit in the rack cabinet.
